(19) United States
(12) Patent Application Publication
(10) Pub. No.: US 2025/0306091 A1
(43) Pub. Date: Oct. 2, 2025

(54) POSITIONING DEVICE OF PROBE CARD

(71) Applicant: YOKOWO CO., LTD., Tokyo (JP)

(72) Inventor: Takeshi TODOROKI, Gunma (JP)

(73) Assignee: YOKOWO CO., LTD., Tokyo (JP)

(21) Appl. No.: 19/087,827

(22) Filed: Mar. 24, 2025

(30) Foreign Application Priority Data
Mar. 26, 2024 (JP) 2024-050524

(51) Int. Cl. G01R 31/28; G01R 1/073

(52) U.S. Cl. CPC G01R 31/2891; G01R 1/07342

(57) ABSTRACT

A positioning device of a probe card includes: a probe card including a probe, which is electrically contactable with an electrode of a device to be measured, and an inspection hole; and a camera configured to capture an image of the device to be measured through the inspection hole. A positional relationship between the probe and a specific peripheral edge portion of the inspection hole is known. Positioning of the probe card is performed by aligning the specific peripheral edge portion with or bringing the specific peripheral edge portion close to a characteristic portion of the device to be measured at a minute interval, in a field of view of the camera.

### CROSS-REFERENCE TO RELATED APPLICATION(S)

This application is based on and claims priority under 35 USC 119 from Japanese Patent Application No. 2024-050524 filed on Mar. 26, 2024, the contents of which are incorporated herein by reference.

### TECHNICAL FIELD

The present invention relates to a positioning device of a probe card.

### BACKGROUND ART

A technique of forming an inspection hole in a probe card, projecting a small bar from the inspection hole, and using the small bar as a mark for alignment between the probe card and a semiconductor element is proposed in Patent Literature 1 below.

### CITATION LIST

### Patent Literature

Patent Literature 1: JPH06-224270A

In Patent Literature 1, there is a problem that a mounting position accuracy of the small bar affects positioning accuracy between the probe card and the semiconductor element.

### SUMMARY

An object of the present invention is to provide a positioning device of a probe card capable of easily positioning a probe card and a device to be measured and improving positioning accuracy. Other objects of the present invention will become apparent based on the present description.

One aspect of the present invention is a positioning device of a probe card including: a probe card including a probe, which is electrically contactable with an electrode of a device to be measured, and an inspection hole; and an imaging unit (a camera) configured to capture an image of the device to be measured through the inspection hole, in which a positional relationship between the probe and a specific peripheral edge portion of the inspection hole is known, and positioning of the probe card is performed by aligning the specific peripheral edge portion with or bringing the specific peripheral edge portion close to a characteristic portion of the device to be measured at a minute interval, in a field of view of the imaging unit.

According to the above aspect of the present invention, the positioning between the probe card and the device to be measured is easy, and positioning accuracy can be improved.

Any combination of the above components and conversion of the expression of the present invention between methods and systems are also effective as aspects of the present invention.

### BRIEF DESCRIPTION OF DRAWINGS

FIG. 1 is a front sectional view of a positioning device 1 of a probe card according to an embodiment of the present invention.

FIG. 2 is a plan view of a probe card 10 viewed from above in the positioning device 1 of a probe card.

### DESCRIPTION OF EMBODIMENTS

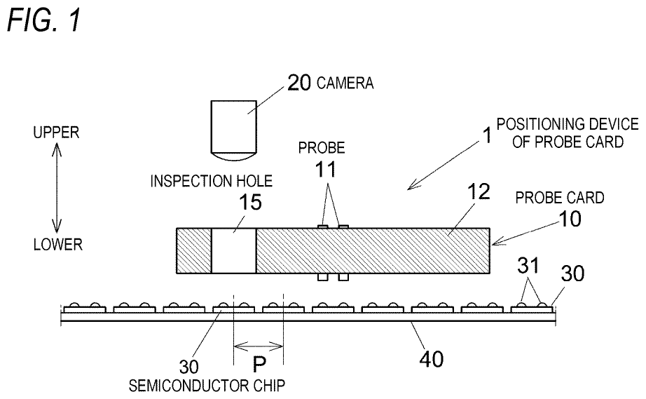

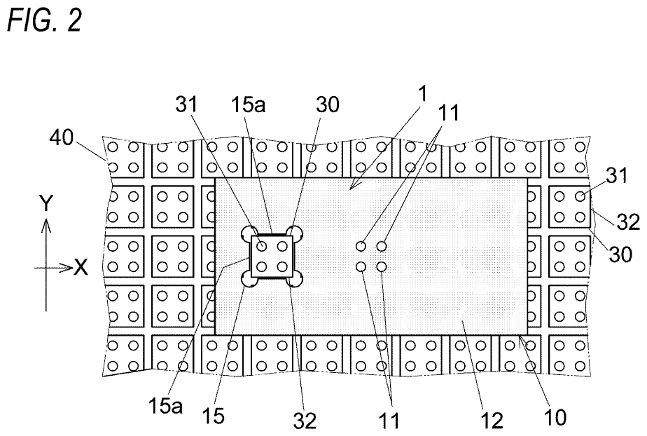

A positioning device of a probe card according to an embodiment of the present invention will be described with reference to FIGS. 1 and 2. For convenience of description, an upper-lower direction is defined in FIG. 1, and an X-Y direction is defined in FIG. 2. As shown in these drawings, a positioning device 1 of a probe card includes a probe card 10 including a plurality of probes 11 and an inspection hole 15, and a chip checking camera 20 as an imaging unit for capturing an image of a semiconductor chip 30 through the inspection hole 15.

The probe card 10 has a configuration in which the plurality of probes 11 are arranged so as to vertically penetrate a plate-like or sheet-like base body 12, and an inspection hole 15 is arranged at a position separated from the plurality of probes 11. The base body 12 may be a rigid substrate or a flexible substrate, but in a case of a flexible substrate, the base body 12 is supported so as not to be deformed during measurement.

The semiconductor chip 30 is an object whose electrical characteristics are measured using the probe card 10, and is a device to be measured. The semiconductor chips 30 are regularly aligned and disposed on a wafer 40. In the shown example, four electrode pads 31 are provided, and four probes 11 of the probe card 10 are disposed correspondingly. An outer shape 32 of the semiconductor chip 30 is generally square or rectangular, and a positional relationship between the outer shape 32 and the electrode pads 31 is known.

In FIG. 2, the chip checking camera 20 as the imaging unit has a field of view in which an image of the semiconductor chip 30, which is viewed through a periphery portion of the inspection hole 15 included in the probe card 10 and the inspection hole 15, can be captured. In the field of view of the chip checking camera 20, the inspection hole 15 has linear peripheral edge portions 15a that are in contact with four sides of the outer shape 32 of the semiconductor chip 30 or that can closely face the four sides at a minute interval, respectively. The positional relationship (a distance and an X-Y direction) between the specific peripheral edge portion 15a and the probe 11 is set or measured in advance and known. When the wafer 40 is movable in the X-Y direction, the probe card 10 and the chip checking camera 20 are fixed. When the wafer 40 is fixed, the probe card 10 and the chip checking camera 20 may be configured to move integrally in the X-Y direction.

In the configuration of the above embodiment, the measurement of the semiconductor chip 30 is performed by the following procedure. First, the wafer 40 is relatively moved with respect to the probe card 10 so that the specific semiconductor chip 30 to be measured on the wafer 40 enters the field of view of the chip checking camera 20, and as shown in FIG. 2, in the field of view of the chip checking camera 20, the peripheral edge portions 15a of the inspection hole 15 are aligned with or closely face the four sides of the outer shape 32 of the semiconductor chip 30 at a minute interval, respectively. Thus, the probe card 10 can be positioned with respect to the semiconductor chip 30 and the wafer 40. Since the positional relationship between the peripheral edge portions 15a and the probes 11 is known, the positional relationship between the probes 11 and the electrode pads 31 of the semiconductor chip 30 is known, and based on the known positional relationship, the wafer 40 is moved in the X-Y direction by a necessary amount, and the four electrode pads 31 are made to face directly below the four probes 11. Thereafter, the probes 11 are lowered relative to the wafer 40 to bring the four probes 11 into electrical contact with the four electrode pads 31, and the electrical characteristics are measured.

In the example of FIG. 1, since the semiconductor chip 30 to be measured imaged by the chip checking camera 20 through the inspection hole 15 and the semiconductor chip 30 located directly below the probe 11 are separated from each other in the X direction by twice an arrangement pitch P of the semiconductor chips 30, the wafer 40 may be moved in the X direction by a distance of 2×P.

According to the present embodiment, the following effects can be achieved.

(1) The positioning device 1 of a probe card uses the probe card 10 including the probes 11, which is electrically contactable with the electrode pads 31 of the semiconductor chip 30 as the device to be measured, and the inspection hole 15, and performs positioning of the probe card 10 by aligning a specific peripheral edge portion of the inspection hole 15 with or bringing the specific peripheral edge portion of the inspection hole 15 close to a characteristic portion of the semiconductor chip 30 at a minute interval, in the field of view of the chip checking camera 20. Therefore, positioning accuracy can be improved as compared with a structure in which a member for positioning is added to the probe card 10. Further, a step of adding a member for positioning is unnecessary.

(2) Since the outer shape 32 of the semiconductor chip 30 on the wafer 40 is generally a square or a rectangle, and the positional relationship between the outer shape 32 and the electrode pads 31 is also known, the probe card 10 can be easily and accurately positioned with respect to the semiconductor chip 30 by a configuration in which the peripheral edge portions 15a of the inspection hole 15 are aligned with or closely face the four sides of the outer shape 32 of the semiconductor chip 30 at a minute interval.

Embodiments of the present invention have been described above with reference to the drawings, but these embodiments are examples of the present invention, and various configurations other than those described above can also be used.

In the above embodiment, a case where the number of electrode pads of the semiconductor chip as the device to be measured and the number of probes coincide with each other is exemplified, but the number of electrode pads and the number of probes do not necessarily have to coincide with each other, and the number of probes may correspond to the number of dummy pads, or the number of probes may be increased so that a plurality of semiconductor chips can be simultaneously measured.

Although the four specific peripheral edge portions are formed in the inspection hole corresponding to the four sides of the semiconductor chip as the device to be measured, two specific peripheral edge portions corresponding to two orthogonal sides of the semiconductor chip may be formed in the inspection hole, and also in this case, positioning in an X direction and a Y direction is possible.

In the above embodiment, the positioning of the semiconductor chip and the probe card (in other words, the positioning of the electrode pads of the semiconductor chip and the probes) is performed by aligning the outer shape of the semiconductor chip which is the device to be measured with the specific peripheral edge portion of the inspection hole formed in the probe card, but the positioning of the device to be measured and the probe card may be performed by aligning a characteristic portion other than the outer shape of the device to be measured with a specific peripheral edge portion of the inspection hole.

Even when the characteristic portion of the device to be measured and the specific peripheral edge portion of the inspection hole do not completely align with each other but are close to each other at a minute interval, the device to be measured and the probe card can be positioned (for example, when the minute interval is sufficiently smaller than a diameter of the electrode pad).

In the above embodiment, the specific peripheral edge portion of the inspection hole has a linear portion having a certain length, but a pointed tip may be used as the peripheral edge portion.

In the above embodiment, the inspection hole formed in the probe card has a shape corresponding to one semiconductor chip, but may have a shape including a plurality of semiconductor chips or a shape including only a characteristic portion of one semiconductor chip and its periphery.

Although the probes are arranged to penetrate the base body of the probe card, in a case of a thin-film probe card, the probes serving as contact points may be arranged only on a surface facing the device to be measured.

According to the present specification, a positioning device of a probe card according to the following aspects is provided.

### (Aspect 1)

A positioning device of a probe card including:
a probe card including a probe, which is electrically contactable with an electrode of a device to be measured, and an inspection hole; and
an imaging unit configured to capture an image of the device to be measured through the inspection hole, in which
a positional relationship between the probe and a specific peripheral edge portion of the inspection hole is known, and
positioning of the probe card is performed by aligning the specific peripheral edge portion with or bringing the specific peripheral edge portion close to a characteristic portion of the device to be measured at a minute interval, in a field of view of the imaging unit.

According to Aspect 1 described above, the probe card including the probe, which is electrically contactable with the electrode of the device to be measured, and the inspection hole in is used, and the positioning of the probe card is performed by aligning the specific peripheral edge portion of the inspection hole with or bringing the specific peripheral edge portion of the inspection hole close to the characteristic portion of the device to be measured at a minute interval, in the field of view of the imaging unit. Therefore, positioning accuracy can be improved as compared with a structure in which a member for positioning is added to the probe card. Further, a step of adding a member for positioning is unnecessary.

### (Aspect 2)

In the positioning device of a probe card,
the characteristic portion of the device to be measured has an outer shape, and
the positioning of the probe card is performed by, at a plurality of positions, aligning the specific peripheral edge portion with or bringing the specific peripheral edge portion close to the outer shape at a minute interval.

According to Aspect 2 described above, since the positional relationship between the outer shape of the device to be measured and the electrode is known, the outer shape is selected as the characteristic portion of the device to be measured, and the peripheral edge portion of the inspection hole is aligned with or closely face the outer shape of the device to be measured at a minute interval, so that the probe card can be easily and accurately positioned with respect to the device to be measured.

### (Aspect 3)

In the positioning device of a probe card,
the positioning of the probe card is performed by aligning the specific peripheral edge portion with or bringing the specific peripheral portion close to two sides perpendicular to each other of the outer shape at a minute interval.

According to Aspect 3 described above, since the positional relationship between the outer shape of the device to be measured and the electrode is known and the specific peripheral edge portion of the inspection hole is aligned with or close to the two sides perpendicular to each other of the outer shape at a minute interval, it is possible to perform positioning in the X direction and the Y direction with high accuracy.

### (Aspect 4)

A probe card including:
a probe that is electrically contactable with an electrode of a device to be measured; and
an inspection hole, in which
the probe card is attached to a positioning device of a probe card including an imaging unit that captures an image of the device to be measured through the inspection hole, and
in order to perform positioning of the probe card by aligning a specific peripheral edge portion of the inspection hole with or bringing the specific peripheral edge portion of the inspection hole close to a characteristic portion of the device to be measured at a minute interval, in a field of view of the imaging unit, a positional relationship between the probe and the specific peripheral edge portion is known.

According to Aspect 4 described above, it is possible to provide the probe card capable of improving positioning accuracy without adding a member for positioning.

(Aspect 5) A probe card including:
a probe that is electrically contactable with an electrode of a device to be measured; and
an inspection hole that enables imaging of the device to be measured by an imaging unit, in which
the inspection hole has a peripheral edge portion that enables adjustment of a position with respect to the device to be measured by imaging through the inspection hole by the imaging unit.

According to Aspect 5 described above, it is possible to provide the probe card capable of position adjustment without adding a member for positioning.

1. A positioning device of a probe card comprising:
a probe card including a probe, which is electrically contactable with an electrode of a device to be measured, and an inspection hole; and
an imaging unit configured to capture an image of the device to be measured through the inspection hole, wherein
a positional relationship between the probe and a specific peripheral edge portion of the inspection hole is known, and
positioning of the probe card is performed by aligning the specific peripheral edge portion with or bringing the specific peripheral edge portion close to a characteristic portion of the device to be measured at a minute interval, in a field of view of the imaging unit.

2. The positioning device of a probe card according to claim 1, wherein
the characteristic portion of the device to be measured has an outer shape, and
the positioning of the probe card is performed by, at a plurality of positions, aligning the specific peripheral edge portion with or bringing the specific peripheral edge portion close to the outer shape at a minute interval.

3. The positioning device of a probe card according to claim 2, wherein
the positioning of the probe card is performed by aligning the specific peripheral edge portion with or bringing the specific peripheral portion close to two sides perpendicular to each other of the outer shape at a minute interval.

4. A probe card comprising:
a probe that is electrically contactable with an electrode of a device to be measured; and
an inspection hole, wherein
the probe card is attached to a positioning device of a probe card including an imaging unit that captures an image of the device to be measured through the inspection hole, and
in order to perform positioning of the probe card by aligning a specific peripheral edge portion of the inspection hole with or bringing the specific peripheral edge portion of the inspection hole close to a characteristic portion of the device to be measured at a minute interval, in a field of view of the imaging unit, a positional relationship between the probe and the specific peripheral edge portion is known.

5. A probe card comprising:
a probe that is electrically contactable to an electrode of a device to be measured; and
an inspection hole that enables imaging of the device to be measured by an imaging unit, wherein
the inspection hole has a peripheral edge portion that enables adjustment of a position with respect to the device to be measured by imaging through the inspection hole by the imaging unit.
